(19) United States
(12) Patent Application Publication
(10) Pub. No.: US 2014/0368723 A1
(43) Pub. Date: Dec. 18, 2014

(54) LENS MODULE AND CAMERA MODULE INCLUDING THE SAME

(71) Applicant: Samsung Electro-Mechanics Co., Ltd., Suwon (KR)

(72) Inventors: Jin Hwa Jung, Suwon (KR); Yong Joo Jo, Suwon (KR); Young Suk Kang, Suwon (KR)

(73) Assignee: Samsung Electro-Mechanics Co., Ltd., Suwon (KR)

(21) Appl. No.: 14/102,479

(22) Filed: Dec. 10, 2013

(30) Foreign Application Priority Data
Jun. 18, 2013 (KR) 10-2013-0069592
Sep. 27, 2013 (KR) 10-2013-0115669

(51) Int. Cl. G02B 13/00; H01L 27/146; H04N 5/225

(52) U.S. Cl. CPC G02B 13/0055; H04N 5/2254; H01L 27/14625; H04N 5/2257
USPC 348/340

(57) ABSTRACT

There is provided a lens module including: a plurality of lenses; and a plurality of interval maintaining members disposed between the plurality of lenses, respectively, and having light-shielding holes formed therein, respectively, so that light input through the plurality of lenses passes therethrough, wherein sizes of the respective light-shielding holes are increased in a downward optical axis direction, and at least one of the plurality of light-shielding holes has a rectangular shape.

### CROSS-REFERENCE TO RELATED APPLICATION

This application claims the benefit of Korean Patent Application No. 10-2013-0069592 filed on Jun. 18, 2013 and Korean Patent Application No. 10-2013-0115669 filed on Sep. 27, 2013 with the Korean Intellectual Property Office, the disclosure of which is incorporated herein by reference.

### BACKGROUND

The present disclosure relates to a lens module and a camera module including the same.

Recently, portable communications terminals such as cellular phones, personal digital assistants (PDA), portable personal computers (PC), and the like, have generally been implemented with the ability to perform the transmission of video data as well as the transmission of text or audio data.

In accordance therewith, camera modules have been standardly installed in portable communications terminals in order to enable the transmission of the video data, video chatting, and the like.

The camera module may include at least one stacked lens, and light passing through the lens may be collected by an image sensor and stored as data in device memories.

However, since external light is refracted while passing through the lens, the light passing through the lens is not directly collected in the image sensor, but arrives at and is reflected by an electronic component in the vicinity of the image sensor, such that it may be introduced to the image sensor.

In addition, light passing through the lens may be scatter-reflected by an inner wall, or the like, of the camera module and be then introduced to the image sensor.

In this case, a flare phenomenon such as light spreading, or the like, may be generated, which may have a negative influence on image quality. Therefore, there is a need to prevent scatter-reflected light in the camera module from being introduced to the image sensor.

### SUMMARY

An aspect of the present disclosure may provide a lens module capable of preventing a phenomenon in which light passing through lenses is scatter-reflected in a camera module and preventing a phenomenon in which unnecessary light is introduced into an image sensor, and a camera module including the same.

According to an aspect of the present disclosure, a lens module may include: a plurality of lenses; and a plurality of interval maintaining members disposed between the plurality of lenses, respectively, and having light-shielding holes formed therein, respectively, so that light input through the plurality of lenses passes therethrough, wherein sizes of the respective light-shielding holes are increased in a downward optical axis direction, and at least one of the plurality of light-shielding holes has a rectangular shape.

The light-shielding hole having the rectangular shape may have a size sufficient to block light, from the light input through the plurality of lenses, in the vicinity of an image sensor.

The light-shielding hole having the rectangular shape may have a size within a range in which it does not interfere with a path of light input to an image sensor in the light input through the plurality of lenses.

The light-shielding hole having the rectangular shape may have a size sufficient to prevent light from being input to portions of an image sensor other than effective pixels thereof.

Each of the plurality of lenses may include a lens function part and a flange part formed at an edge of the lens function part and contacting the plurality of interval maintaining members.

The flange part may have a light shielding material coated thereon or a light shielding film attached thereto.

The interval maintaining members may be formed of an opaque material.

According to another aspect of the present disclosure, a lens module may include: a plurality of lenses; and a plurality of interval maintaining members disposed between the plurality of lenses, respectively, and having light-shielding holes formed therein, respectively, so as to control an amount of light passing through the plurality of lenses, wherein at least one of the plurality of light-shielding holes formed in the plurality of interval maintaining members has a rectangular shape, and a ratio between lengths of the respective sides of the light-shielding hole having the rectangular shape corresponds to a ratio between lengths of the respective sides of an image sensor.

All of the light-shielding holes may have the rectangular shape.

Only a light-shielding hole, among the plurality of light-shielding holes, disposed to be closest to the image sensor, may have the rectangular shape.

The light-shielding hole having the rectangular shape may have a size sufficient to block light, from the light input through the plurality of lenses, input in the vicinity of the image sensor.

The light-shielding hole having the rectangular shape may have a size within a range in which it does not interfere with a path of light input to the image sensor in the light input through the plurality of lenses.

The light-shielding hole having the rectangular shape may have a size sufficient to prevent light from being input to portions other than effective pixels of the image sensor.

An inner wall of a light-shielding hole, among the plurality of light-shielding holes, disposed to be closest to the image sensor, may be formed as an inclined surface.

A diameter of a light-shielding hole, among the plurality of light-shielding holes, disposed to be closest to the image sensor, may be increased in a downward optical axis direction.

According to another aspect of the present disclosure, a camera module may include: a lens barrel including at least one lens disposed on an optical axis; and an image sensor disposed below the lens barrel, wherein the lens barrel includes a through-hole opened so that external light can be input therethrough, the through-hole being formed in a shape corresponding to that of the image sensor.

The through-hole may be formed to have a rectangular shape so as to correspond to a rectangular shape of the image sensor.

A ratio between lengths of the respective sides of the through-hole may correspond to a ratio between lengths of the respective sides of the image sensor.

The through-hole may have a size sufficient to block external light input in the vicinity of the image sensor.

The through-hole may have a size within a range in which it does not interfere with a path of external light input to the image sensor.

The through-hole may have a size sufficient to prevent light from being input to portions other than effective pixels of the image sensor.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is an exploded perspective view of a camera module according to an exemplary embodiment of the present disclosure;

FIG. 2 is an exploded perspective view of a lens barrel and a lens module provided in the camera module according to the exemplary embodiment of the present disclosure;

FIG. 3 is a schematic cross-sectional view of the camera module according to the exemplary embodiment of the present disclosure;

FIG. 4 is a perspective view of a first interval maintaining member provided in the camera module according to the exemplary embodiment of the present disclosure;

FIGS. 5A and 5B are perspective views showing an interval maintaining member and an image sensor in the case in which a light shielding hole has a circular shape;

FIG. 6 is a perspective view of the interval maintaining member and the image sensor provided in the camera module according to the exemplary embodiment of the present disclosure; and

FIG. 7 is a schematic cross-sectional view for describing a process of blocking unnecessary light in the camera module according to the exemplary embodiment of the present disclosure.

### DETAILED DESCRIPTION

Hereinafter, embodiments of the present invention will be described in detail with reference to the accompanying drawings. The invention may, however, be embodied in many different forms and should not be construed as being limited to the embodiments set forth herein. Rather, these embodiments are provided so that this disclosure will be thorough and complete, and will fully convey the scope of the invention to those skilled in the art. In the drawings, the shapes and dimensions of elements may be exaggerated for clarity, and the same reference numerals will be used throughout to designate the same or like elements.

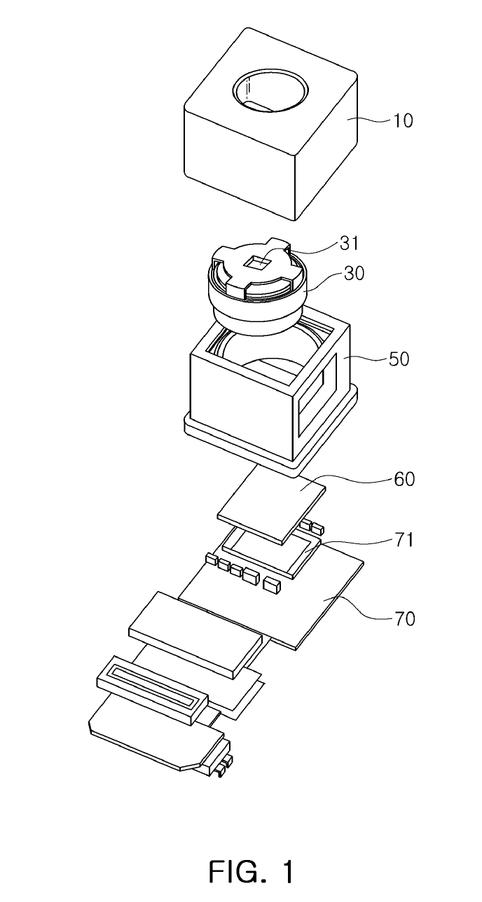

FIG. 1 is an exploded perspective view of a camera module according to an exemplary embodiment of the present disclosure.

Referring to FIG. 1, the camera module according to the exemplary embodiment of the present disclosure may include a lens barrel 30, a housing 50, a case 10, an infrared (IR) filter 60, an image sensor 71, and a printed circuit board 70.

First, terms with respect to directions will be defined. An optical axis direction refers to a vertical direction based on the lens barrel 30, and a horizontal direction refers to a direction perpendicular to the optical axis direction.

The lens barrel 30 may have a hollow cylindrical shape so that a plurality of lenses for imaging an imaging subject may be received therein, wherein the plurality of lenses may be provided in the lens barrel 30 on an optical axis.

The plurality of lenses may include an interval maintaining member disposed therebetween in order to maintain an interval therebetween and may configure, together with the interval maintaining member, a lens module 20.

The plurality of lenses corresponding to a required number thereof may be stacked depending on a design of the lens module 20, and the respective lenses may have optical characteristics such as the same refractive index, different refractive indices, or the like.

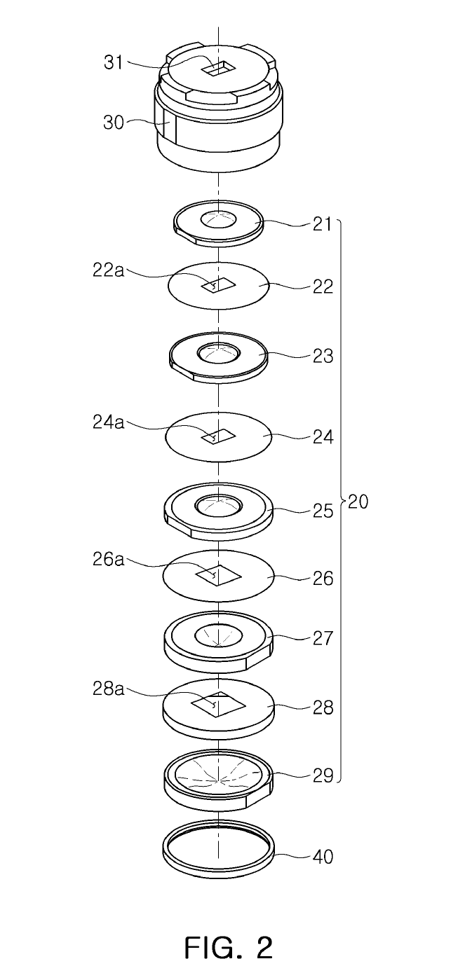

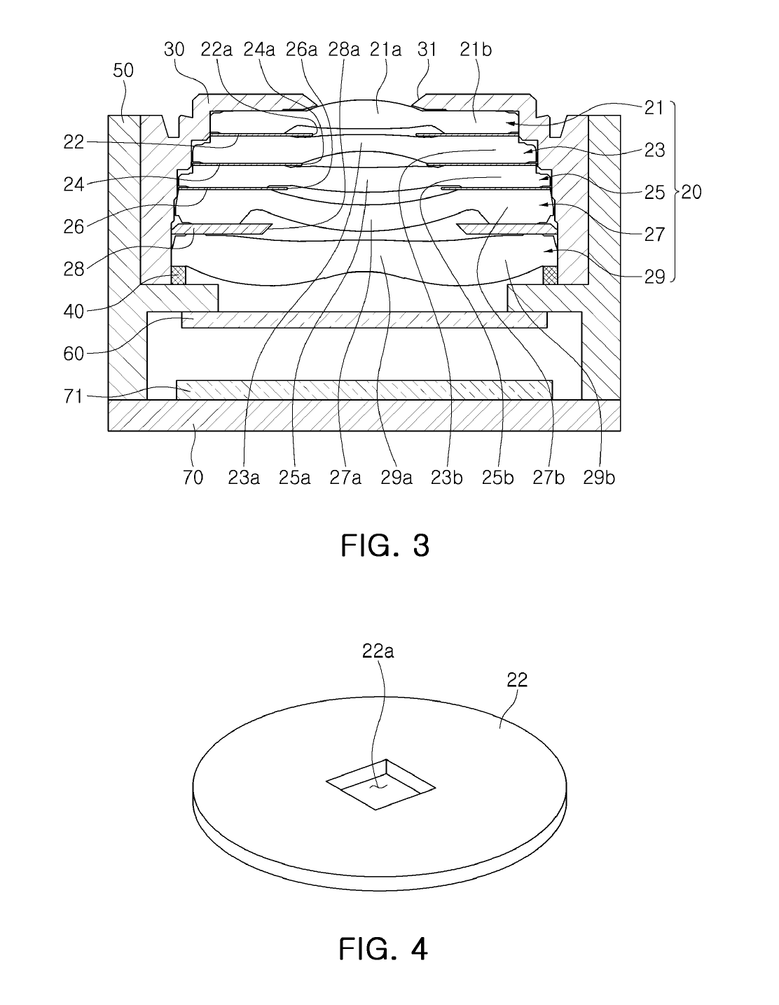

The lens module 20 may be described in detail with reference to FIGS. 2 through 3.

The lens barrel 30 may be coupled to the housing 50. More specifically, the lens barrel 30 may be disposed in the housing 50.

Here, the lens barrel 30 may be moved in the optical axis direction for auto-focusing.

In order to move the lens barrel 30 in the optical axis direction, an inner portion of the housing 50 may be provided with an actuator (not shown) including a voice coil motor.

The actuator (not shown) may include a coil (not shown), a magnet (not shown), and a yoke (not shown), wherein the coil (not shown) may move the lens barrel 30 in the optical axis direction by attractive force and repulsive force from the magnet (not shown) adjacent thereto.

The magnet (not shown) may generate a predetermined magnetic field, generate driving force by electromagnetic influence between the magnet (not shown) and the coil (not shown) when power is applied to the coil (not shown), and move the lens barrel 30 in the optical axis direction by the driving force.

However, a moving unit of the lens barrel 30 is not limited to the actuator including the voice coil motor (VCM). That is, various schemes such as a mechanical driving scheme, a piezoelectric driving scheme using a piezoelectric element, or the like, may be used.

The lens barrel 30 may be moved by the operation as described above to perform an auto focusing or zooming function.

The case 10 may be coupled to the housing 50 so as to enclose an outer surface of the housing 50 and serve to shield electromagnetic waves generated at the time of driving the camera module.

That is, the camera module may generate electromagnetic waves at the time of being driven. In the case in which electromagnetic waves as described above are emitted to the outside, it may have an effect on other electronic components to cause communications interference or a malfunction.

Therefore, in order to prevent electromagnetic waves from being emitted to the outside, the case 10 may be coupled to the housing 50.

Here, the case 10 may be grounded to a ground pad (not shown) provided on the printed circuit board 70 to shield electromagnetic waves.

The case 10 may have a through-hole formed in an upper portion thereof so that external light may be input through the lens barrel 30, wherein the external light input through the through-hole may be received in the image sensor 71 through the lens.

The image sensor 71 such as a charge coupled device (CCD) or a complementary metal oxide semiconductor (CMOS) may be mounted on the printed circuit board 70 through wire bonding, and the printed circuit board 70 may be coupled to the bottom of the housing 50.

An image of an imaging subject may be collected by the image sensor 71 and stored as data in a device memory, and the stored data may be displayed as the image by a display medium in the device.

Here, the lens barrel 30 and the image sensor 71 may have the infrared (IR) filter 60 disposed therebetween.

That is, the infrared filter 60 may be disposed below the lens barrel 30.

When the external light passing through the lens passes through the infrared filter 60, infrared rays may be removed from the external light. Therefore, introduction of infrared rays into the image sensor 71 may be prevented.

The infrared filter 60 may be formed of a glass material and be manufactured by depositing several materials having different refractive indices on a surface in order to cut off light in an infrared region.

The infrared filter 60 may be bonded to an inner surface of the housing 50. That is, the infrared filter 60 and the housing 50 may be bonded to each other through an ultraviolet (UV) adhesive (not shown).

FIG. 2 is an exploded perspective view of a lens barrel and a lens module provided in the camera module according to the exemplary embodiment of the present disclosure; and FIG. 3 is a schematic cross-sectional view of the camera module according to the exemplary embodiment of the present disclosure.

The lens module 20 provided in the camera module according to the exemplary embodiment of the present disclosure will be described with reference to FIGS. 2 and 3.

The lens module 20 may include a plurality of lenses and a plurality of interval maintaining members respectively disposed between the plurality of lenses. That is, the lens module 20 may include first to fifth lenses 21, 23, 25, 27, and 29, and the interval maintaining members 22, 24, 26, and 28 each disposed between the first to fifth lenses 21, 23, 25, 27, and 29.

Although the case in which the lens module includes five lenses has been shown in FIGS. 2 and 3, the lens module may include an amount of lenses equal to or less than 5 or equal to or more than 5 depending on a resolution desired to be implemented.

The first to fifth lenses 21, 23, 25, 27, and 29 may be formed of glass, a glass molding material, a thermosetting resin, a thermoplastic resin, or plastic.

The first to fifth lenses 21, 23, 25, 27, and 29 may generally have positive refractive power or negative refractive power. More specifically, the first to fifth lenses 21, 23, 25, 27, and 29 may have different refractive powers, respectively.

The first lens 21 may be disposed in the lens barrel 30 and be disposed in the lens barrel 30 so as to be close to an imaging subject.

The first to fifth lenses 21, 23, 25, 27, and 29 may be sequentially stacked.

More specifically, the second lens 23 may be disposed below the first lens 21 in the optical axis direction, and the fifth lens 29 may be disposed so as to be the closest to the image sensor 71.

The first to fifth lenses 21, 23, 25, 27, and 29 may include lens function parts 21a, 23a, 25a, 27a, and 29a, and flange parts 21b, 23b, 25b, 27b, and 29b, respectively.

The lens function parts 21a, 23a, 25a, 27a, and 29a may substantially refract input light reflected from the subject. To this end, the lens function parts 21a, 23a, 25a, 27a, and 29a may have a concave shape, a convex shape, or a meniscus shape.

The flange parts 21b, 23b, 25b, 27b, and 29b may be formed at edges of the lens function parts 21a, 23a, 25a, 27a, and 29a, respectively, and contact the lens barrel 30, the interval maintaining members 22, 24, 26, and 28, or the other lenses.

In addition, the flange parts 21b, 23b, 25b, 27b, and 29b may have a light shielding material coated thereon or a light shielding film attached thereto in order to prevent unnecessary light from being transmitted therethrough.

Meanwhile, the first to fifth lenses 21, 23, 25, 27, and 29 may have the interval maintaining members 22, 24, 26, and 28 disposed therebetween, respectively.

Here, the first and second lenses 21 and 23 may have a first interval maintaining member 22 disposed therebetween, the second and third lenses 23 and 25 may have a second interval maintaining member 24 disposed therebetween, the third and fourth lenses 25 and 27 may have a third interval maintaining member 26 disposed therebetween, and the fourth and fifth lenses 27 and 29 may have a fourth interval maintaining member 28 disposed therebetween.

In addition, the fifth lens 29 may selectively have a press-fitting ring 40 disposed therebelow.

The press-fitting ring 40 may serve to fix the first to fifth lenses 21, 23, 25, 27, and 29 to an inner portion of the lens barrel 30.

The flange parts 21b, 23b, 25b, 27b, and 29b of first to fifth lenses 21, 23, 25, 27, and 29 may contact each other through the first to fourth interval maintaining members 22, 24, 26, and 28, respectively, as shown in FIG. 3.

The first to fourth interval maintaining members 22, 24, 26, and 28 may be disposed between the first to fifth lenses 21, 23, 25, 27, and 29, respectively, and maintain distances between the first to fifth lenses 21, 23, 25, 27, and 29 by a predetermined interval, respectively.

Further, in order to block light passing through outer sides (that is, the flange parts 21b, 23b, 25b, 27b, and 29b) of the lens function parts 21a, 23a, 25a, 27a, and 29a, the first to fourth interval maintaining members 22, 24, 26, and 28 may be formed of an opaque material or be coated with a light-shielding material.

The first to fourth interval maintaining members 22, 24, 26, and 28 may be formed of a non-ferrous metal. For example, the first to fourth interval maintaining members 22, 24, 26, and 28 may be made of a copper or aluminum material.

In this case, there may be advantages that the interval maintaining members 22, 24, 26, and 28 may be easily formed and a cost required for manufacturing the interval maintaining members 22, 24, 26, and 28 may be decreased.

The first to fourth interval maintaining members 22, 24, 26, and 28 may be disposed between the first to fifth lenses 21, 23, 25, 27, and 29, respectively, to control an amount of light passing through the first to fifth lenses 21, 23, 25, 27, and 29, respectively.

That is, the first to fourth interval maintaining members 22, 24, 26, and 28 may have light-shielding holes 22a, 24a, 26a, and 28a formed therein, respectively, so as to penetrate therethrough in the optical axis direction, and light input through the plurality of lenses may pass through the light-shielding holes 22a, 24a, 26a, and 28a.

Here, the light-shielding holes 22a, 24a, 26a, and 28a formed in the interval maintaining members 22, 24, 26, and 28, respectively, may be sequentially called a first light-shielding hole 22a, a second light-shielding hole 24a, a third light-shielding hole 26a, and a fourth light-shielding hole 28a from an upper portion in the optical axis direction.

Sizes of the first to fourth light-shielding holes 22a, 24a, 26a, and 28a may be determined depending on refractive powers of the first to fifth lenses 21, 23, 25, 27, and 29 and be enough for light passing through the first to fifth lenses 21, 23, 25, 27, and 29 to be input to the image sensor 71.

In addition, the sizes of the respective light-shielding holes 22a, 24a, 26a, and 28a may be increased in a downward optical axis direction. This may be not to hinder a path of external light input to the image sensor 71 since the external light may be widely spread while passing through the plurality of lenses.

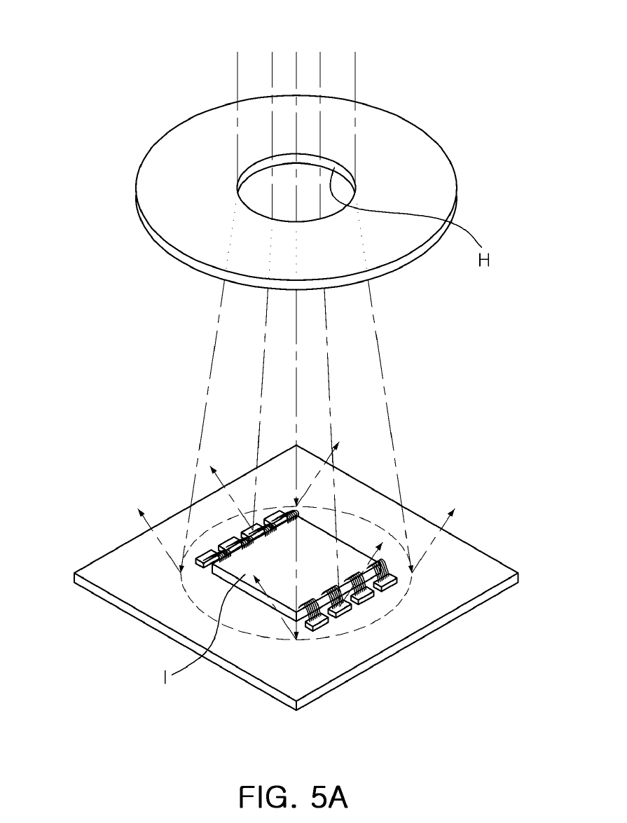

FIG. 4 is a perspective view of a first interval maintaining member provided in the camera module according to the exemplary embodiment of the present disclosure.

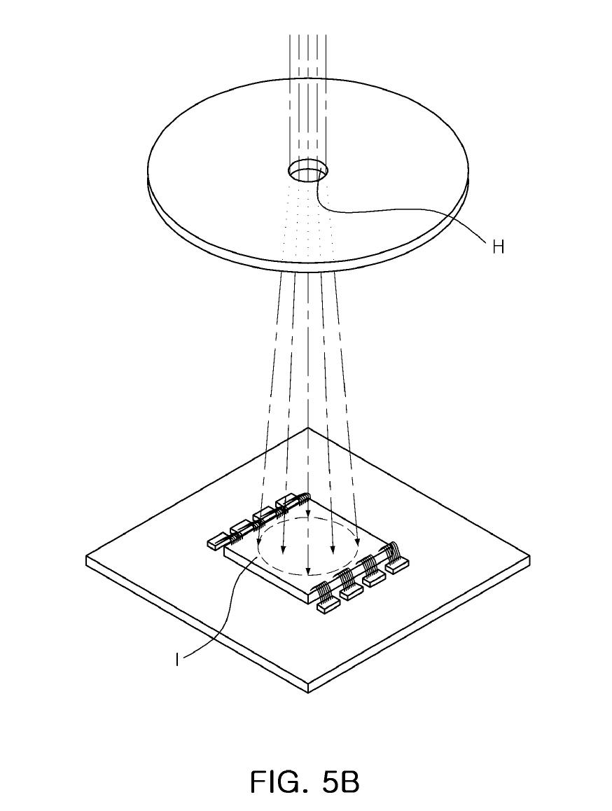

In addition, FIGS. 5A and 5B are perspective views showing an interval maintaining member and an image sensor in the case in which a light shielding hole has a circular shape.

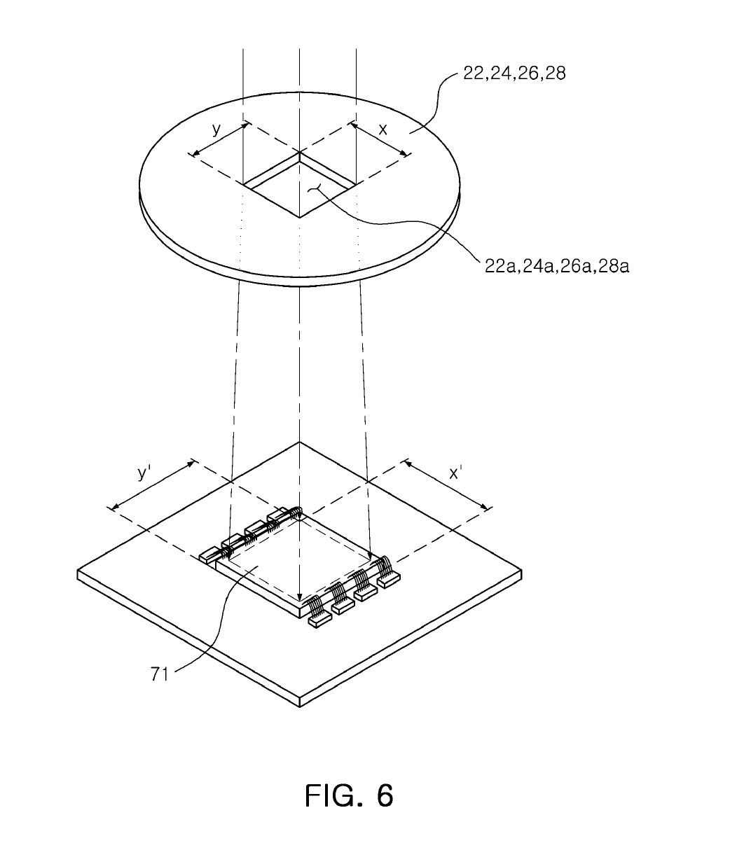

Further, FIG. 6 is a perspective view of the interval maintaining member and the image sensor provided in the camera module according to the exemplary embodiment of the present disclosure.

The interval maintaining members 22, 24, 26, and 28 provided in the camera module according to the exemplary embodiment of the present disclosure will be described with reference to FIGS. 4 through 6.

The first to fourth interval maintaining members 22, 24, 26, and 28 may have the first to fourth light-shielding holes 22a, 24a, 26a, and 28a formed therein, respectively, in order to block unnecessary light.

Here, the unnecessary light may be light in external light passing through the plurality of lenses other than light input to the image sensor 71. More specifically, the unnecessary light may mean light input to and reflected from an electronic component, a lead wire, or the like, in the vicinity of the image sensor 71 and may generally mean light input to portions other than effective pixels (pixels of portions actually used for a screen) of the image sensor 71 in the light input to the image sensor 71.

Here, planes of the first to fourth light-shielding holes 22a, 24a, 26a, and 28a may have a polygonal shape such as a rectangular shape, or the like.

Since the image sensor 71 generally has a rectangular shape, in the case in which the first to fourth light-shielding holes 22a, 24a, 26a, and 28a have a circular shape, the external light passing through the first to fourth light-shielding holes 22a, 24a, 26a, and 28a may be scatter-reflected by the electronic component in the vicinity of the image sensor 71 and then arrive at the image sensor 71 or be input to the portions other than the effective pixels of the image sensor 71, whereby there is a risk that a flare phenomenon, or the like, will occur.

That is, in the case in which a light-shielding hole H has a circular shape as shown in FIG. 5A, a phenomenon in which external light passing through the light-shielding hole H having the circular shape arrives at and is scatter-reflected by an electronic component in the vicinity of an image sensor I having a rectangular shape may occur.

In addition, in the case in which a diameter of the light-shielding hole H is decreased so that the external light is not input to the electronic component in the vicinity of the image sensor I as shown in FIG. 5B, an amount of light input to the image sensor I may be insufficient.

That is, the external light passing through the light-shielding hole H having the circular shape may be spread in the circular shape and be input to the image sensor I. Here, since the image sensor I generally has a rectangular shape, it may be difficult for the external light input in the circular shape to be input in accord with effective pixels of the image sensor I having a rectangular shape.

However, as shown in FIG. 6, in the camera module according to the exemplary embodiment of the present disclosure, since the first to fourth light-shielding holes 22a, 24a, 26a, and 28a are implemented to have a polygonal shape such as a rectangular shape, or the like, corresponding to a shape of the image sensor 71, a phenomenon in which unnecessary light is input in the vicinity of the image sensor 71 may be prevented.

That is, in the case in which the plurality of light-shielding holes 22a, 24a, 26a, and 28a are implemented to have the rectangular shape, external light passing through the light-shielding holes 22a, 24a, 26a, and 28a may also be spread and input in the rectangular shape. Therefore, the external light may only be input into the effective pixels of the image sensor 71 having the rectangular shape.

In other words, when sizes of the plurality of light-shielding holes 22a, 24a, 26a, and 28a having the rectangular shape are appropriately controlled, the external light passing through the plurality of light-shielding holes 22a, 24a, 26a, and 28a may be input only into the effective pixels of the image sensor 71 having the rectangular shape.

To this end, a ratio (y/x) between lengths of the respective sides of the light-shielding holes 22a, 24a, 26a, and 28a having the rectangular shape may correspond to a ratio (y′/x′) between lengths of the respective sides of the image sensor 71.

Here, the light-shielding holes 22a, 24a, 26a, and 28a having the rectangular shape may have a size that is determined within the range in which they may prevent the external light from being input in the vicinity of the image sensor 71 and may have a size within a range in which they do not interfere with a path of the light input to the image sensor 71 in the external light input through the plurality of lenses.

In addition, the light-shielding holes 22a, 24a, 26a, and 28a having the rectangular shape may have a size at which they may prevent the light from being input to the portions other than the effective pixels of the image sensor 71.

In other words, in the lens module according to the exemplary embodiment of the present disclosure, the sizes of the light-shielding holes 22a, 24a, 26a, and 28a having the rectangular shape are controlled, whereby the unnecessary light in the external light passing through the plurality of lenses may be blocked and the external light may be input only to the image sensor 71.

Meanwhile, although the case in which five lenses are provided in the lens module 20 and fourth interval maintaining members 22, 24, 26, and 28 are disposed between the respective lenses 21, 23, 25, 27, and 29, respectively, has been shown in the accompanying drawings, the numbers of lenses and interval maintaining members are not limited thereto.

In addition, although the case in which all of the first to fourth light-shielding holes 22a, 24a, 26a, and 28a have the rectangular shape has been shown in the accompanying drawings, the present disclosure is not limited thereto. That is, only the light-shielding hole of at least one of the plurality of interval maintaining members may also be formed to have the rectangular shape.

That is, one or more of the first to fourth light-shielding holes 22a, 24a, 26a, and 28a may be formed to have the rectangular shape or all of the first to fourth light-shielding holes 22a, 24a, 26a, and 28a may be formed to have the rectangular shape. Particularly, only the fourth light-shielding holes 28a disposed to be closest to the image sensor 71 may also be formed to have the rectangular shape.

In addition, as shown in FIGS. 1 and 2, a through-hole 31 itself of the lens barrel 30 opened so that the external light is input may also be formed in a polygonal shape such as a rectangular shape, or the like.

That is, a size and a shape of the through-hole 31 or sizes and shapes of the first to fourth light-shielding holes 22a, 24a, 26a, and 28a may correspond to those of the image sensor 71.

A detailed description for a size of the through-hole 31 will be replaced by a description for a size of the light-shield hole having the rectangular shape described above.

In the case in which the image sensor 71 has the rectangular shape, the through-hole 31 or the first to fourth light-shielding holes 22a, 24a, 26a, and 28a may also be formed to have the rectangular shape, and in the case in which the image sensor 71 has another shape, the through-hole 31 or the first to fourth light-shielding holes 22a, 24a, 26a, and 28a may also be formed in a shape corresponding to that of the image sensor 71.

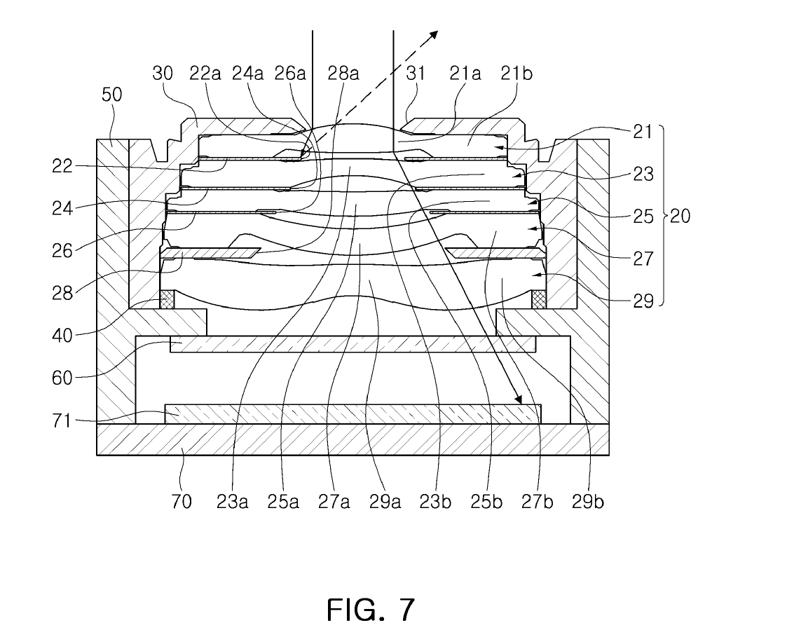

FIG. 7 is a schematic cross-sectional view for describing a process of blocking unnecessary light in the camera module according to the exemplary embodiment of the present disclosure.

A process of blocking unnecessary light by the first to fourth interval maintaining members 22, 24, 26, and 28 provided in the camera module according to the exemplary embodiment of the present disclosure will be described with reference to FIG. 7.

External light input to the camera module may pass through the plurality of lenses 21, 23, 25, 27, and 29 provided in the lens barrel 30, pass through the infrared filter 60, and be then collected in the image sensor 71.

In addition, the light collected in the image sensor 71 may be converted into electrical signals to configure an image.

Here, the light refracted while passing through the plurality of lenses 21, 23, 25, 27, and 29 is not collected in the image sensor 71, but may be scatter-reflected by the electronic component in the vicinity of the image sensor 71 or be scatter-reflected by an inner wall, or the like, of the housing 50 and then arrive at the image sensor 71.

In the case in which the scatter-reflected light is collected in the image sensor 71 as described above, a deterioration phenomenon or a flare phenomenon may occur in the image.

In the case in which light is reflected or scattered in an optical device, it may be overlapped with an image of an imaging subject originally desired to be observed, such that image quality may be deteriorated.

That is, since the light scatter-reflected and then arriving at the image sensor may cause a flare phenomenon such as light blurring, or the like, it may have a bad effect on image quality.

However, in the camera module according to the exemplary embodiment of the present disclosure, in order to block scatter-reflected light other than light directly collected in the image sensor 71, it may be preferable that the first to fourth light-shielding holes 22a, 24a, 26a, and 28a in the first to fourth interval maintaining members 22, 24, 26, and 28 are formed to have an appropriate size.

That is, the unnecessary light other than the light actually arriving directly at the image sensor 71 in the light input from the outside may be blocked by the first to fourth light-shielding holes 22a, 24a, 26a, and 28a.

Further, only the sizes of the first to fourth light-shielding holes 22a, 24a, 26a, and 28a are controlled without using a separate component for blocking the unnecessary light, whereby the flare phenomenon due to the scattered reflection may be prevented.

Particularly, the unnecessary light may be naturally blocked in a process in which the external light passes through the plurality of lenses 21, 23, 25, 27, and 29.

In other words, even though a separate component is not attached to one surface of the infrared filter positioned over the image sensor in order to prevent the light passing through the lens module from being scatter-reflected, a phenomenon in which the scatter-reflected light is input to the image sensor may be prevented.

Further, according to the exemplary embodiment of the present disclosure, since the unnecessary light is blocked in the process in which the external light passes through the lens module 20, the scattered reflection itself of the light in the camera module may not be generated.

Meanwhile, as shown in FIG. 7, an inner wall of the fourth light-shielding hole 28a disposed to be closest to the image sensor 71 may be formed as an inclined surface.

Further, the fourth light-shielding hole 28a may be formed so that a diameter thereof becomes larger downwardly in the optical axis direction.

Since the external light input to the camera module is widely spread in the process in which it passes through the plurality of lenses 21, 23, 25, 27, and 29, the inner wall of the fourth light-shielding hole 28a may be inclined in a movement direction of the external light depending on an input angle of the external light.

In this case, it may be preferable that an inclined angle of the inner wall of the light-shielding hole 28a is formed so that the unnecessary light is not input to the image sensor 71.

As set forth above, with the lens module and the camera module including the same according to the exemplary embodiment of the present disclosure, a phenomenon in which the light passing through the lenses from being scatter-reflected in the camera module may be prevented, and a phenomenon in which the unnecessary light is introduced into the image sensor may be prevented.

While exemplary embodiments have been shown and described above, it will be apparent to those skilled in the art that modifications and variations could be made without departing from the spirit and scope of the present disclosure as defined by the appended claims.

What is claimed is:

1. A lens module comprising:
a plurality of lenses; and
a plurality of interval maintaining members disposed between the plurality of lenses, respectively, and having light-shielding holes formed therein, respectively, so that light input through the plurality of lenses passes therethrough,
wherein sizes of the respective light-shielding holes are increased in a downward optical axis direction, and
at least one of the plurality of light-shielding holes has a rectangular shape.

2. The lens module of claim 1, wherein the light-shielding hole having the rectangular shape has a size sufficient to block light, from the light input through the plurality of lenses, in the vicinity of an image sensor.

3. The lens module of claim 1, wherein the light-shielding hole having the rectangular shape has a size within a range in which it does not interfere with a path of light input to an image sensor in the light input through the plurality of lenses.

4. The lens module of claim 1, wherein the light-shielding hole having the rectangular shape has a size sufficient to prevent light from being input to portions of an image sensor other than effective pixels thereof.

5. The lens module of claim 1, wherein each of the plurality of lenses includes a lens function part and a flange part formed at an edge of the lens function part and contacting the plurality of interval maintaining members.

6. The lens module of claim 5, wherein the flange part has a light shielding material coated thereon or a light shielding film attached thereto.

7. The lens module of claim 1, wherein the interval maintaining members are formed of an opaque material.

8. A lens module comprising:
a plurality of lenses; and
a plurality of interval maintaining members disposed between the plurality of lenses, respectively, and having light-shielding holes formed therein, respectively, so as to control an amount of light passing through the plurality of lenses,
wherein at least one of the plurality of light-shielding holes formed in the plurality of interval maintaining members has a rectangular shape, and
a ratio between lengths of the respective sides of the light-shielding hole having the rectangular shape corresponds to a ratio between lengths of the respective sides of an image sensor.

9. The lens module of claim 8, wherein all of the light-shielding holes have the rectangular shape.

10. The lens module of claim 8, wherein only a light-shielding hole, among the plurality of light-shielding holes, disposed to be closest to the image sensor, has the rectangular shape.

11. The lens module of claim 8, wherein the light-shielding hole having the rectangular shape has a size sufficient to block light, from the light input through the plurality of lenses, input in the vicinity of the image sensor.

12. The lens module of claim 8, wherein the light-shielding hole having the rectangular shape has a size within a range in which it does not interfere with a path of light input to the image sensor in the light input through the plurality of lenses.

13. The lens module of claim 8, wherein the light-shielding hole having the rectangular shape has a size sufficient to prevent light from being input to portions other than effective pixels of the image sensor.

14. The lens module of claim 8, wherein an inner wall of a light-shielding hole, among the plurality of light-shielding holes, disposed to be closest to the image sensor, is formed as an inclined surface.

15. The lens module of claim 8, wherein a diameter of a light-shielding hole, among the plurality of light-shielding holes, disposed to be closest to the image sensor, becomes larger in a downward optical axis direction.

16. A camera module comprising:
a lens barrel including at least one lens disposed on an optical axis; and
an image sensor disposed below the lens barrel,
wherein the lens barrel includes a through-hole opened so that external light can be input therethrough, the through-hole being formed in a shape corresponding to that of the image sensor.

17. The camera module of claim 16, wherein the through-hole is formed to have a rectangular shape so as to correspond to a rectangular shape of the image sensor.

18. The camera module of claim 17, wherein a ratio between lengths of the respective sides of the through-hole corresponds to a ratio between lengths of the respective sides of the image sensor.

19. The camera module of claim 16, wherein the through-hole has a size sufficient to block external light input in the vicinity of the image sensor.

20. The camera module of claim 16, wherein the through-hole has a size within a range in which it does not interfere with a path of external light input to the image sensor.

21. The camera module of claim 16, wherein the through-hole has a size sufficient to prevent light from being input to portions other than effective pixels of the image sensor.
